(19) United States
(12) Patent Application Publication
(10) Pub. No.: US 2023/0314351 A1
(43) Pub. Date: Oct. 5, 2023

(54) COMPUTER-IMPLEMENTED METHOD FOR GENERATING EVENT-AVERAGED AND TIME-RESOLVED SPECTRA

(71) Applicant: Scienta Omicron AB, Uppsala (SE)

(72) Inventor: Jan KNUDSEN, Södra Sandby (SE)

(73) Assignee: Scienta Omicron AB, Uppsala (SE)

(21) Appl. No.: 18/012,209

(22) PCT Filed: Jun. 10, 2021
(86) PCT No.: PCT/SE2021/050557

§ 371 Date: Dec. 21, 2022

(30) Foreign Application Priority Data
Jun. 25, 2020 (SE) 2050757-0

(51) Int. Cl. G01N 23/227

(52) U.S. Cl. CPC G01N 23/227

(57) ABSTRACT

A computer-implemented method is described for generating event-averaged and time-resolved spectra, from a plurality of time-resolved spectra of charged particles emitted from a surface (3) of a sample (2), at which surface (3) an event is repeated cyclically, the method comprising the steps of receiving (101), from the charged particle analyser (1), the plurality of time-resolved spectra covering a plurality of events, obtaining (102) at least one selected part (9, 10) of the series of time-resolved spectra, matching (103) the at least one selected part (9, 10) with other parts of the series of time-resolved spectra to find similar parts, and thereby determining points in time for other events in the plurality of events, and generating (104) the event-averaged and time-resolved spectra of the event based on the series of time-resolved charged particle energy spectra and the determined points in time.

### TECHNICAL FIELD

The present invention relates to charged-particle spectroscopy and more specifically to the generation of event-averaged and time-resolved spectra from a plurality of time-resolved spectra of charged particles emitted from a surface of a sample, at which an event is repeated cyclically, wherein the time-resolved spectra are obtained with a charged particle analyser.

### BACKGROUND ART

Understanding surface structures present at reaction conditions and correlating this to their catalytic properties have for decades been a rapidly growing research field, and a number of new in-situ surface sensitive techniques have been developed for catalysis research. One of these techniques are ambient pressure X-ray photo-electron spectroscopy (APXPS), which can be used to simultaneously probe the surface atoms, adsorbed atoms and molecules on the surface, and the gas phase in the near vicinity of the surface at mbar pressures while a chemical reaction to be studied is taking place at the surface. APXPS that use a charged particle analyser to detect photo-electrons from the element of interest is a rather slow technique with typical acquisition times of minutes to obtain a decent signal-to-noise ratio even when a powerful 4th generation synchrotron light source is used. The long acquisition time is not caused by slow response time of the charged particle analysers, that easily reach ms or us time resolution, but rather by the weak photo electron probe signal. It simply takes time to detect the weak signal of elastically scattered core electrons from a given element before a peak fitting can be performed unambiguously as the signal is measured atop a large background signal of inelastically scattered electrons. Therefore, in situ catalysis research performed with charged particle analysers have until now been limited to studies of surfaces at steady state at certain fixed temperature, gas composition, and pressure conditions and it has been impossible to follow kinetics of surfaces in-situ and in particular how fast catalyst surfaces respond to changed temperature, gas compositions, and pressure.

The above problems are also present when using other techniques such as, e.g., SXRD, PM-IRAS, and PES, as well as when the charged particles that are analysed are not electrons but positively or negatively charged ions or various elementary particles to give a few examples.

Thus, there is a need for improving the quality of the signal, such as e.g., the signal-to-noise ratio, when using techniques, such as those mentioned, to follow fast reactions.

### SUMMARY OF THE INVENTION

An object of the present invention is to provide a method for improving a signal quality measure such as, e.g., signal-to-noise ratio, in charged particle spectra when using charged particle analysers.

This object is achieved with the computer-implemented method according to the independent claim 1.

Another object of the present invention is to provide a computer program for generating event-averaged and time-resolved spectra, comprising instructions which, when executed by at least one processor in a computer cause the at least one computer to carry out a method for improving a signal quality measure such as, e.g., signal-to-noise ratio, in charged particle spectra when using charged particle analysers.

This object is achieved with the computer-implemented method according to the independent claim 14.

Further advantages are obtained with the features of the dependent claims.

According to a first aspect of the invention a computer-implemented method is provided for generating event-averaged and time-resolved spectra, from a plurality of time-resolved spectra of charged particles emitted from a surface of a sample, at which surface an event is repeated cyclically, wherein the plurality of time-resolved spectra are obtained with a charged particle analyser. The method comprises the step of receiving, from the charged particle analyser, the plurality of time-resolved spectra covering a plurality of events, wherein the time between events adjacent in time defines a time period, and wherein each of the plurality of time-resolved spectra comprises information on the distribution of charged particles as a function of a physical property for an interval of magnitudes for the physical property. The method is characterized in that it also comprises the step of obtaining at least one selected part of the series of time-resolved spectra, wherein the at least one selected part comprises spectra from at least a part of the interval of magnitudes for the physical property and a part of a time period when the event takes place. The method is also characterized in that is also comprises the steps of matching the at least one selected part with other parts of the series of time-resolved spectra to find similar parts, and thereby determining points in time for other events in the plurality of events, and generating the event-averaged and time-resolved spectra of the event based on the series of time-resolved charged particle energy spectra and the determined points in time.

The information on the distribution may be an intensity reflecting the number of charged particles as a function of the physical property.

By obtaining at least one selected part and matching said selected part with other parts of the series of time-resolved spectra to find similar parts it is possible to accurately determine the points in time for subsequent events in the plurality of events. Thus, the method is not sensitive to variations in the time period between two subsequent events. This makes it possible to generate the event-averaged and time-resolved spectra with superior signal quality such as, e.g., a superior signal-to-noise ratio, from spectra with poor signal quality acquired cyclically. The cyclic repetition of the event may be obtained in many different ways. The cyclic repetition of the event may be obtained by oscillating the conditions at the surface. Examples on such oscillating conditions comprise oscillating the pressure at the surface, oscillating the temperature at the surface, oscillating the gas composition at the surface, oscillating an electromagnetic field at the surface, oscillating an optical field incident on the surface and oscillating the gas temperature at the surface.

The invention uses pattern recognition in the raw data to determine each event and for generating the event-averaged signal rather than an external triggering signal from the oscillating conditions.

The at least one selected part may be obtained based on data input by a user. Alternatively, the at least one selected part may be obtained automatically using a computer program.

The at least one selected part may be obtained during reception of the series of time-resolved spectra, wherein the matching is started during reception of the series of time-resolved spectra and wherein the event-averaged and time-resolved spectra is generated during reception of the series of time-resolved spectra. By starting the process to generate the event-averaged an time-resolved spectra while the reception of the series of time-resolved spectra is ongoing the acquisition of spectra may be ended when a sufficiently good result has been achieved.

The generation of the event-averaged and time-resolved spectra may be ended when an end condition is fulfilled, wherein the end condition is one of: reception of an end input signal, and a signal quality measure signal quality measure of the event-averaged and time-resolved spectra being better than a predetermined value. The end condition makes it possible to end the acquisition of spectra as soon as possible. This makes it possible to save time at, e.g., the X-ray source used for the generation charged particles at the surface of the sample. If a synchrotron is used to generate the X-rays the time at the X-ray source is usually a very limited resource.

The end condition may be that the signal-to-noise ratio is above a predetermined threshold. This is an objective measure of the signal quality.

The signal quality measure could alternatively be one of peak-to-value ratio, and the contrast of the event-averaged image formed by the plurality of spectra.

The computer-implemented method may also comprise the step of sending out control signals for controlling the cycling of the events. This may be advantageous for example when the method is also configured to perform the other steps automatically.

The control signals may control at least one of: a gas mixture at the surface, a gas pressure at the surface, a temperature at the surface, an electromagnetic field at the surface, an optical field incident on the surface and a gas temperature at the surface. When the computer-implemented method has determined that the event-averaged spectra is sufficiently good it may automatically alter the physical conditions of the experiment and start generating another spectra.

The plurality of time-resolved spectra may comprises a plurality of data points, and wherein the matching is performed by subtracting, the data in each data point in the selected part from the data in the corresponding data point in other parts of the series of time-resolved spectra and adding the differences, to obtain a result as a function of point in time for the other part of the series, and determining the points in time for the other events by finding minima in the obtained result. The data in each data point may be an intensity reflecting the number of charged particles as a function of the physical property. In other words, for each successive other part the differences between the data in each data point in the selected part and the data in the corresponding data point in the other part are integrated. This results in an integrated difference as a function of time. The integrated difference as a function of time describe how well the selected part match the successive other parts when the selected part is moved along the time axis in the series of time-resolved spectra. A minima in the integrated difference reflects a matching event.

The matching may comprise fitting a polynomial to the integral of the differences between the other parts of the series and the selected part to obtain the timings for the events. By fitting a polynomial to the integral the point of time for the event may be determined with better accuracy.

The events may be used in the generation of the event-averaged and time-resolved spectra only if the minima for the events are below a predetermined threshold. By using only some of the minima the quality of the event-averaged spectrum is improved.

The matching may be performed by convolution of the selected part with other parts of the series of time-resolved spectra, to obtain a result as a function of point in time for the other part of the series, and determining the points in time for the other events by finding maxima in the obtained result. Convolution is an alternative to the above described integration of differences between data points.

The matching may comprise fitting a polynomial to the convolution of the selected part with other parts of the series of time-resolved spectra to obtain the result. By fitting a polynomial to the convolution the point of time for the event may be determined with better accuracy.

The physical property is one of a starting angle for the charged particle, the energy of the charged particle and a starting position for the charged particle.

According to a second aspect of the present invention a computer program is provided for generating event-averaged and time-resolved spectra, comprising instructions which, when executed by at least one processor in a computer cause the computer to carry out the method according to the first aspect of the present invention. The computer may be a remote computer.

In the following preferred embodiments of the invention will be described with reference to the drawings.

### BRIEF DESCRIPTION OF THE DRAWINGS

FIG. 1 shows an arrangement in which a charged particle analyser is used to measure spectra of a reaction at a sample.

FIG. 2 is a three dimensional (3D) waterfall plot acquired with the setup of FIG. 1 of a large number of spectra captured over 3 oscillations of the gas composition inducing events on the surface.

FIG. 3 is the corresponding image plot of FIG. 2 together with an enlarged image of the selected part.

FIG. 4 is a flow scheme of the method according to an embodiment of the invention.

FIG. 5 shows the integral over the absolute difference between the intensity of each data point in a selected part and the corresponding data point in a comparison part as a function of data point displacement.

FIG. 6 shows a single CO adsorption-desorption event on the surface and is cut from the image plot in FIG. 3.

FIG. 7 shows a single spectrum from the image in FIG. 6.

FIG. 8 shows an event-averaged image averaged over 48 events corresponding to FIG. 6.

FIG. 9 shows a single spectrum from the event-averaged image in FIG. 8.

### DETAILED DESCRIPTION

The invention is described in the following illustrative and non-limiting detailed description of exemplary embodiments, with reference to the appended drawings. In the drawings, similar features in different drawings are denoted by the same reference numerals. The drawings are not drawn to scale.

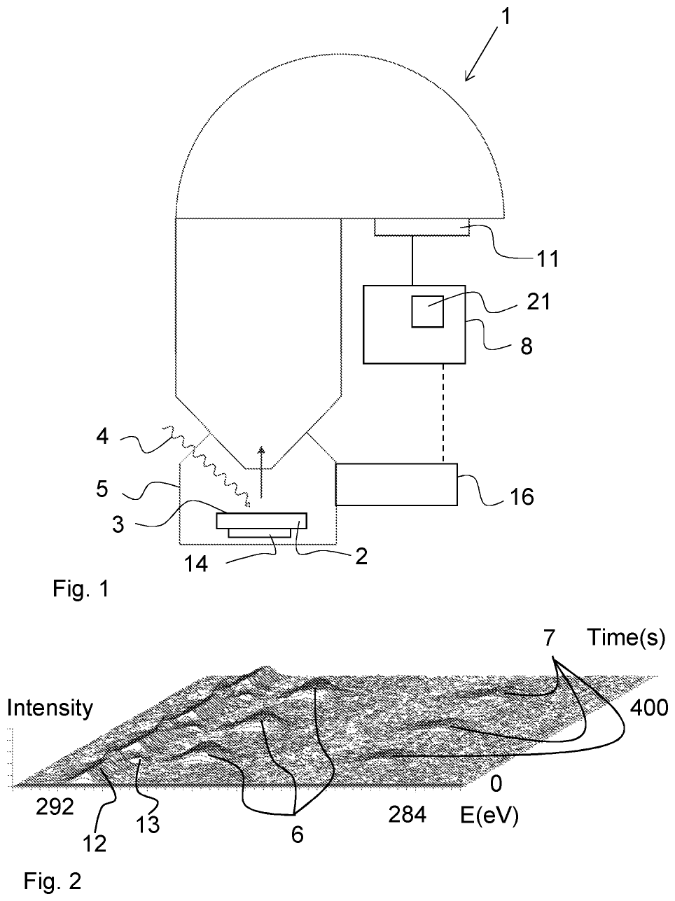

FIG. 1 shows an arrangement in which a charged particle analyser 1, with a detector 11, is used to measure spectra of a reaction at a sample 2, or more specifically at the surface 3 of the sample 2. Electromagnetic radiation 4 is arranged to illuminate the surface of the sample in order to induce emission of charged particles from the surface 3 of the sample 2. The arrangement includes a gas cell 5 in which the sample is arranged. The gas cell 5 has a sufficiently small volume to allow a rapidly oscillating gas composition in the gas cell. The arrangement also comprises a heater 14 to allow the sample to be rapidly heated. Thus, when studying a reaction at the surface 3 of the sample it is possible to vary the temperature, the pressure and the gas composition at the surface 3 of the sample 2. A computer 8 with a processor 21 is connected to the charged particle analyser 1 and receives data from the detector 11 of the charged particle analyser 1. The arrangement in FIG. 1 also comprises a gas supply unit 16 provides gas of the correct mixture and pressure to the gas cell 5. The computer 8 may also be configured to control the gas oscillation with regard to pressure and/or mixture and/or the heater 14, as is shown with the dotted line between the gas supply unit 16 and the computer 8. The computer 8 could be a remote computer.

We will now describe the study of a process of carbon dioxide (CO) adsorption on a surface and the opposite process of CO desorption. The gas composition in the gas cell 5 is repeatedly switched by alternating pulses of CO rich (45 sec duration of 2.7:1 CO:O₂) and O₂ rich (100 sec duration of 1:2.7 CO:O₂) gas mixtures. While the gas composition alternates between CO rich and O₂ rich gas mixtures electromagnetic radiation in the form of X-rays illuminates the surface 3 of the sample 2 which induces emission of photo-electrons from the surface 3 of the sample 2. Some of the photoelectrons that are emitted from the surface 3 enters the charged particle analyser 1 and are analysed with respect to their kinetic energy, such that a spectrum is captured. Spectra are collected continuously with a high framerate or acquisition rate of about 1-50 Hz. The detector may be a camera detector, a delay-line detector or a pulse counting detector. These different types of detectors are well known to persons skilled in the art and will not here be explained in more detail.

FIG. 2 shows a waterfall plot of a large number of spectra captured over three gas-composition oscillations with the arrangement of FIG. 1. The waterfall plot shows the binding energy, the count of electrons or the intensity and the time. The CO₂ gas phase signal is visible as peaks 12 and its apparent binding energy shift, that signals a work function shift on the sample surface caused by CO adsorption, is shown as peaks 13. The CO in the gas is also visible as peaks 6 in FIG. 2 while the CO adsorbed on the surface 3 of the sample 2 is shown as peaks 7 in FIG. 2. The increase in CO gas concentration in the gas cell is seen as the start of the CO gas peaks 6 while the increase in O₂ gas concentration is seen as the end of the CO gas peaks 6. The adsorption and desorption of CO from the surface 3 constitutes two events which are repeated cyclically by oscillating the gas composition as described above.

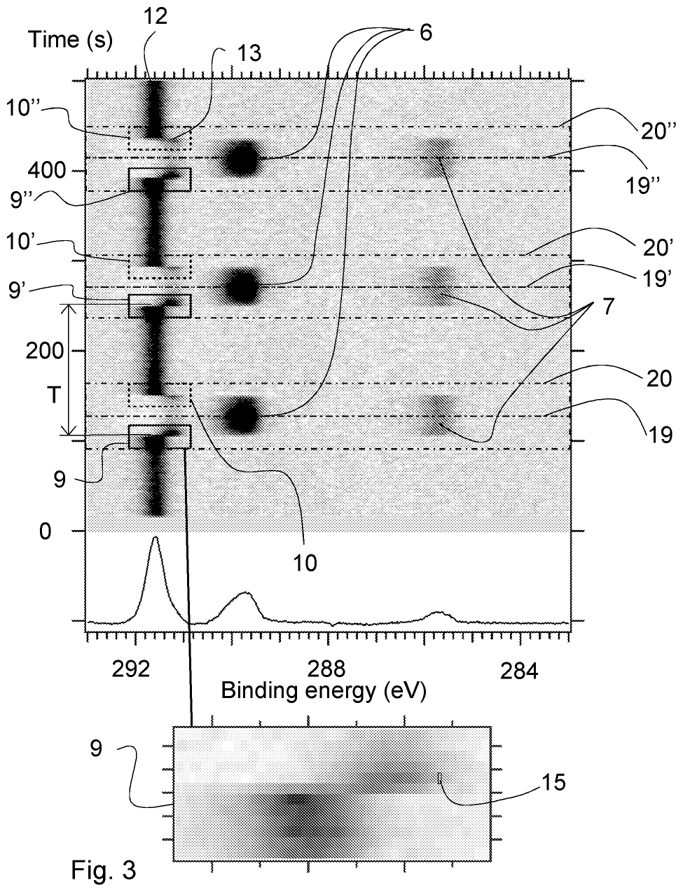

FIG. 3 is an image plot corresponding to FIG. 2, and covers a plurality of time-resolved spectra. The gas composition is changed from O₂ rich to CO rich at times 105 s, at 250 s and at 395 s in FIG. 3. The gas composition is changed from CO rich to O₂ rich at times 150 s, 295 s and 440 s in FIG. 3. Each one of the gas composition changes is and event. As can be seen in FIG. 3 the plurality of time-resolved spectra in FIG. 3 covers a plurality of events, wherein the time between events adjacent in time defines a time period T. Each of the plurality of time-resolved spectra comprises information on the distribution of charged particles as a function of a physical property in the form of the amount of CO and O₂, respectively within an interval being the two different compositions. The plurality of spectra is a matrix with data, wherein the number of pixels/data points 15 in the time direction is equal to the number of spectra registered per second times the registration time whereas the number of pixels/data points 15 in the energy direction is equal to the energy resolution of the detector times the energy interval. The data in each data point is an intensity which reflects the number of charged particles in that data point. In FIG. 3 a darker colour corresponds to a higher intensity.

As stated above the physical property could alternatively be the temperature of the sample or the gas pressure. The gas pressure or temperature could be changed within an interval, preferably two different values.

At the bottom of FIG. 3 is shown a time averaged spectra of the image plot.

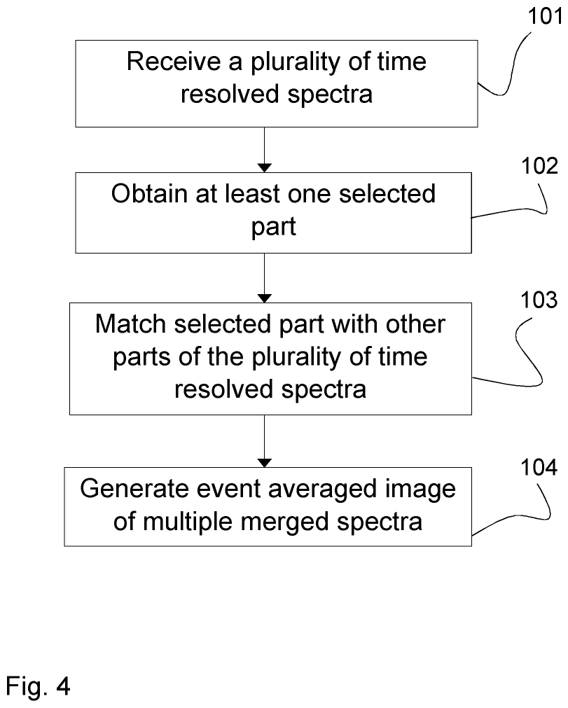

The method according to the invention will now be described with reference also to FIG. 4 which is a flow scheme of the method according to an embodiment of the invention. In a first step 101 the computer 8 receives, from the charged particle analyser 3, a plurality of time-resolved spectra covering a plurality of events. The time between events adjacent in time defines a time period T as is indicated in FIG. 3. Each one of the plurality of time-resolved spectra comprises information on the distribution of charged particles as a function of a physical property for an interval of magnitudes for the physical property. In the example in FIGS. 2 and 3 the physical property is the binding energy and is in the interval 283 to 293 eV.

As an alternative to the binding energy the physical property may be, e.g., one of a starting angle for the charged particle, the energy of the charged particle and a starting position for the charged particle.

The series of time-resolved spectra shown in FIGS. 2 and 3 constitutes an acquisition matrix in which the number of pixels/data points 15 in the energy direction depends on the number of pixels/data points 15 in the detector 11 of the charged particle analyser 1, and the number of pixels/data points 15 in the time direction depends on the framerate/acquisition rate per second and the acquisition time.

In the second step 102 at least one selected part 9 of the series of time-resolved spectra is obtained. The selected part may be obtained based on user input but may alternatively be obtained automatically. In FIG. 3, a first selected part 9 and a second selected part 10 are obtained. FIG. 3 also shows an enlargement of the first selected part 9 in which single data points, such as the marked data point 15, are visible. The selected parts comprise spectra from at least a part of the interval of magnitudes for the physical property and a part of a time period when the event takes place. Thus, the first selected part 9 covers the time period for the CO adsorption event and the energy interval covering the binding energy shift that signals a work function shift on the sample surface caused by CO adsorption on the surface. The second selected part 10 covers the reverse event of CO desorption. The obtained first selected part 9 and second selected part 10 may alternatively be called stamp signals. The first selected part 9 and the second selected part 10 constitutes parts of the series of time-resolved spectra which is equivalent to the acquisition matrix.

In a third step 103 the first selected part 9 and the second selected part 10 are matched with other parts of the series of time-resolved spectra to find similar parts, and thereby determining points in time for other events in the plurality of events. Each one of the first selected part 9 and the second selected part 10 comprise a number of pixels/data points 15.

In order to match the first selected part 9 and the second selected part 10 with similar parts of the acquisition matrix, each one of the first selected part 9 and the second selected part 10 is displaced forward in single pixel steps in the time direction of the acquisition matrix, i.e., one spectra in the time direction to a new comparison part of the acquisition matrix. For each pixel displacement the integral over the absolute difference between the intensity of each data point in the selected part and the intensity of the corresponding pixel in the comparison part is determined.

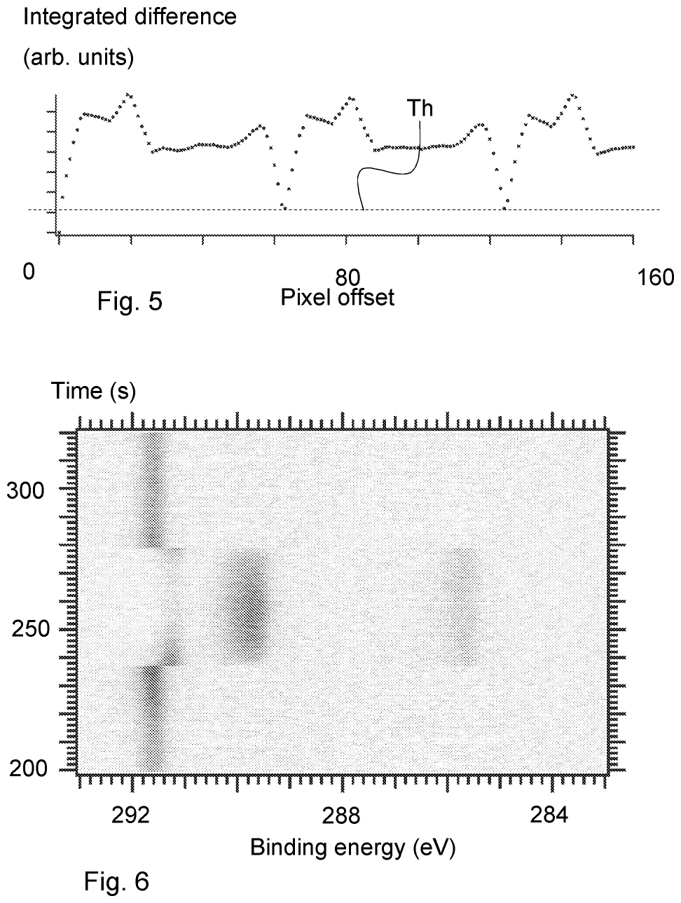

Once the first selected part 9 is placed above the same spectral fingerprint of a transition happening on the surface it will result in a minimum of the integral value—i.e. a match is found. A match is found for the first selected part 9 when the first selected part 9 is compared with the first match part 9′ and the second match part 9″. A match is found for the second selected part 10 when the second selected part 10 is compared with the third match part 10′ and the fourth match part 10″. The integral value as a function of pixel offset is shown in FIG. 5. In FIG. 3 the first selected part and the second selected part only covers a part of the energy interval measured with the detector of the charged particle analyser. The energy interval used in FIG. 3 is chosen to cover a clear change in the spectra during the event. The size of the energy interval may of course be chosen differently.

An appropriate function is fitted to each minimum to determine the minimum point as precise as possible. This procedure leads to a table of timing signals that defines the transition to a CO covered surface.

The result is a table with the exact times for the forward switching events to a CO covered surface and one table with the exact times for the backward switching event when CO desorbs. Based on the exact times the spectra from different events may be accurately event-averaged. After having determined the exact times for the forward switching and the backward switching events forward merging parts 19, 19′, 19″ and backward merging parts 20, 20′, 20″, are cut from the acquisition matrix and are event-averaged. Even if there is a jitter in the timing for the event a correct event averaging is achieved.

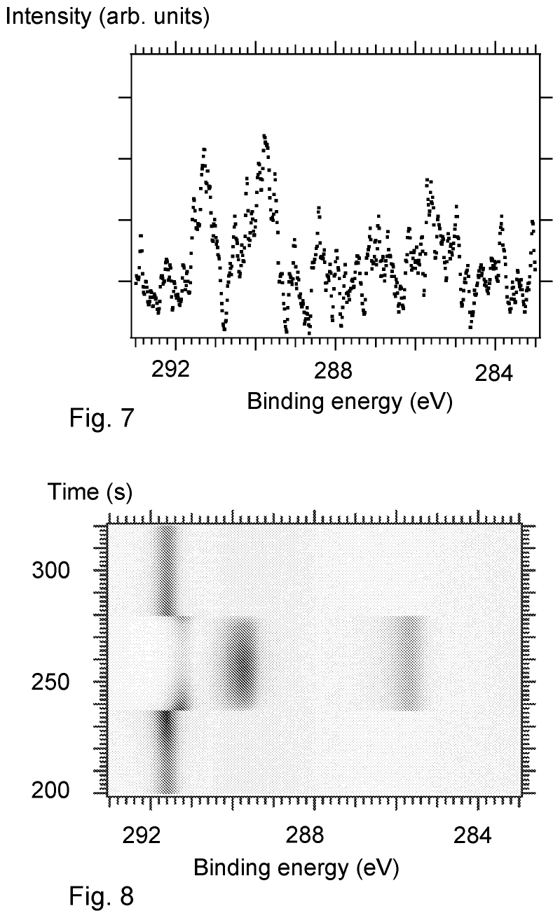

FIG. 6 shows an image of a spectrum including a process of CO adsorption on the surface of the sample in FIG. 1 and the process in the opposite direction. FIG. 7 shows a single spectrum from the image in FIG. 5.

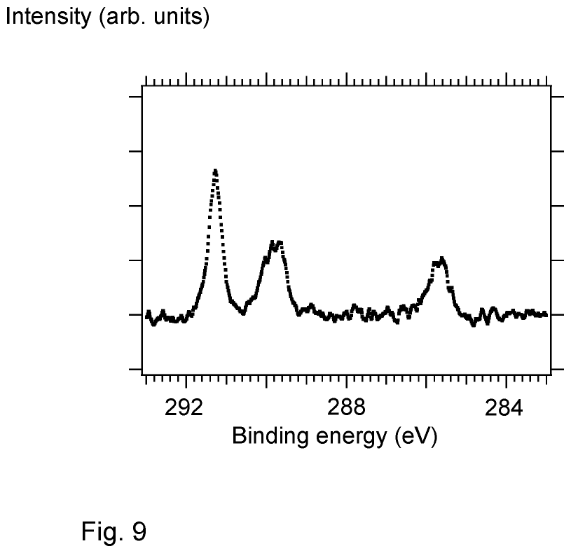

Based on the determined timing for the events the forward merging parts 19, 19′, 19″ and the backward merging parts 20, 20′, 20″, are cut from the acquisition matrix and are event-averaged to generate, in a fourth step 104, the image of FIG. 8, which shows an event-averaged image of multiple merged spectra as shown in FIG. 6. Due to a possible variation in the time period between the first event and the second event the time averaging between the events is not perfectly accurate. Thus, the event-averaged image in FIG. 8 is not absolutely accurate around time 260 s. However, as no interesting change occurs in the spectra between the events any error in the event-averaged image would be irrelevant. In the event-averaged image the entire energy range of the detector has been used. From the event-averaged image in FIG. 8, an event-averaged and time-resolved spectra of the event may be extracted as shown in FIG. 9. As can be clearly seen from a comparison of FIGS. 7 and 9 the signal-to-noise ratio of the spectra is greatly improved with the method according to the invention. It is of course possible to use other measures of quality than the signal-to-noise ratio, such as, e.g., the peak-to-value ratio or the contrast of the event-averaged image formed by the plurality of spectra.

In order to optimize the quality of the event-averaged image of multiple merged spectra not all events need to be used in the averaging. A threshold Th may be applied to the curve in FIG. 5. Only events which belong to a minima being below the threshold Th will be used in the event averaging. It is also possible to use all events which belong to minima above the threshold in a separate event averaging

The at least one selected part may be obtained during reception of the series of time-resolved spectra. By arranging the computer-implemented method in this way the matching may start during reception of the series of time-resolved spectra and the event-averaged and time-resolved spectra may be generated during reception of the series of time-resolved spectra. This makes it possible to study the generation of the event-averaged image of multiple merged spectra or the event-averaged and time-resolved spectrum as shown in FIG. 8 and FIG. 9, respectively, in real time. This makes it possible to end the averaging when the results of FIGS. 8 and 9 are sufficiently good. The generation of the event-averaged and time-resolved spectra may be ended when an end condition is fulfilled, The end condition may be one of: reception of an end input signal, and a signal quality measure of the event-averaged time-resolved spectra being better than a predetermined value.

The above described embodiments may be altered in many ways without departing from the scope of the invention which is limited only by means of the appended claims and their limitations.

1. A computer-implemented method for generating event-averaged and time-resolved spectra, from a plurality of time-resolved spectra of charged particles emitted from a surface of a sample, at which surface an event is repeated cyclically, wherein the plurality of time-resolved spectra are obtained with a charged particle analyser, the method comprising the steps of
receiving, from the charged particle analyser, the plurality of time-resolved spectra covering a plurality of events, wherein the time between events adjacent in time defines a time period, and wherein each of the plurality of time-resolved spectra comprises information on the distribution of charged particles as a function of a physical property for an interval of magnitudes for the physical property, characterized in that it also comprises the steps of
obtaining at least one selected part of the series of time-resolved spectra, wherein the at least one selected part comprises spectra from at least a part of the interval of magnitudes for the physical property and a part of a time period when the event takes place,
matching the at least one selected part with other parts of the series of time-resolved spectra to find similar parts, and thereby determining points in time for other events in the plurality of events, and
generating the event-averaged and time-resolved spectra of the event based on the series of time-resolved charged particle energy spectra and the determined points in time.

2. The computer-implemented method according to claim 1, wherein the at least one selected part is obtained based on data input by a user.

3. The computer-implemented method according to claim 1, wherein the at least one selected part is obtained during reception of the series of time-resolved spectra, wherein the matching is started during reception of the series of time-resolved spectra and wherein the event-averaged and time-resolved spectra is generated during reception of the series of time-resolved spectra.

4. The computer-implemented method according to claim 1, wherein the generation of the event-averaged and time-resolved spectra is ended when an end condition is fulfilled, wherein the end condition is one of: reception of an end input signal, and a signal quality measure of the event-averaged time-resolved spectra being better than a predetermined value.

5. The computer-implemented method according to claim 4, wherein the end condition is that the signal-to-noise ratio is above a predetermined threshold.

6. The computer-implemented method according to claim 1, also comprising the step of sending out control signals for controlling the cycling of the events.

7. The computer-implemented method according to claim 6, wherein the control signals control at least one of: a gas mixture at the surface, a gas pressure at the surface, a temperature at the surface, an electromagnetic field at the surface, an optical field incident on the surface and a gas temperature at the surface.

8. The computer-implemented method according to claim 1, wherein the plurality of time-resolved spectra comprises a plurality of data points, and wherein the matching is performed by subtracting, the data in each data point in the selected part from the data in the corresponding data points in other parts of the series of time-resolved spectra and adding the differences, to obtain a result as a function of point in time for the other part of the series, and determining the points in time for the other events by finding minima in the obtained result.

9. The computer-implemented method according to claim 8, wherein the matching comprises fitting a polynomial to the sum of the differences between the other parts of the series and the selected part to obtain the timings of the events.

10. The computer-implemented method according to claim 8, wherein events are used in the generation of the event-averaged and time-resolved spectra only if the minima for the events are below a predetermined threshold.

11. The computer-implemented method according to claim 1, wherein the matching is performed by convolution of the selected part with other parts of the series of time-resolved spectra, to obtain a result as a function of point in time for the other part of the series, and determining the points in time for the other events by finding maxima in the obtained result.

12. The computer-implemented method according to claim 11, wherein the matching comprises fitting a polynomial to the convolution of the selected part with other parts of the series of time-resolved spectra to obtain the result.

13. The computer-implemented method according to claim 1, wherein the physical property is one of a starting angle for the charged particle, the energy of the charged particle and a starting position for the charged particle.

14. A computer program for generating event-averaged and time-resolved spectra, comprising instructions which, when executed by at least one processor in a computer cause the computer to carry out the method according to claim 1.
